(19) United States
(12) Patent Application Publication
(10) Pub. No.: US 2003/0197516 A1
(43) Pub. Date: Oct. 23, 2003

(54) Apparatus for controlling contactor motion in a position sensor

(76) Inventors: Don Bird, Chatham (CA); Russell Miles Modien, Chatham (CA); Kenneth Peter Nydam, Chatham (CA)

Correspondence Address: Siemens Corporation, Intellectual Property Department, 186 Wood Avenue South, Iselin, NJ, 08830, US

(21) Appl. No.: 10/251,052

(22) Filed: Sep. 20, 2002

Related U.S. Application Data
(60) Provisional application No. 60/373,543, filed on Apr. 18, 2002.

(51) Int. Cl. G01B 7/00; G01B 3/30; G01R 35/00

(52) U.S. Cl. 324/699; 73/1.79; 324/601

(57) ABSTRACT

A slider assembly for use in a linear or rotary position sensor having a board that includes ink strips. The slider assembly includes a base element having a plunger for attachment to an object whose position is being detected. Finger elements extend from the base element, wherein the finger elements contact the ink strips and are biased against the ink strips. A spring device having first and second spring elements is also included, wherein the first and second spring elements contact portions of the board that do not include the ink strips. The contact portions are biased against the board to reduce relative motion between the finger elements and the ink strips.

### CROSS REFERENCE TO RELATED APPLICATION AND PRIORITY CLAIM

This application claims the benefit of U.S. Provisional Application No. 60/373,543 (Attorney Docket No. 2002 P 06545 US) filed on Apr. 18, 2002 in the name of Russell Miles Modien, Kenneth Peter Nydam and Don Bird and entitled A METHOD OF CONTROLLING CONTACTOR FORCE IN A CONTACTING POSITION SENSOR, which is incorporated by reference herein in its entirety.

### FIELD OF THE INVENTION

This invention relates to linear and rotary position sensors, and more particularly, to a spring device having first and second spring elements each of which include contact surfaces that are biased against the board to reduce relative motion of sensor finger elements relative to an ink strip.

### BACKGROUND OF THE INVENTION

Several devices utilized in motor vehicles include components that wear after repeated use. A device having such components is a contact position sensor that detects the position of an object such as an armature. Referring to FIG. 1, portions of a linear position sensor 10 having a slider assembly 12 is shown. The slider assembly 12 is positioned adjacent a board 32 having first 28 and second 30 ink strips which may be resistive inks used in forming a sensing circuit for detecting position. In another configuration, one of the ink strips may be conductive and the other resistive.

The slider assembly 12 includes a base 14 and a plunger 16 that is adapted to be received by an armature. The base 14 includes a center member 18 located between first 20 and second 22 arms which extend outwardly from the base 14 to form a substantially U-shaped configuration. The first 20 and second 22 arms include first 24 and second 26 finger elements which are adapted to contact the first 28 and second 30 ink strips, respectively, so as to form electrical contact. In use, the first 24 and second 26 finger elements move across the first 28 and second 30 ink strips in accordance with corresponding armature movement. This provides an output, such as a voltage output, which is proportional to the relative position of the first 24 and second 26 finger elements with respect to the first 28 and second 30 ink strips.

The first 20 and second 22 arms and first 24 and second 26 finger elements are fabricated from a resilient material having spring properties. The slider assembly 12 is positioned relative to the board 32 such that the first 24 and second 26 finger elements exert a spring force for biasing the first 24 and second 26 finger elements against the first 28 and second 30 ink strips. This provides a predetermined contact pressure suitable for minimizing wear of the first 28 and second 30 ink strips.

During typical motor vehicle operation the slider assembly 12 is frequently subjected to vibrations which are of sufficient magnitude to overcome the spring force exerted by the first 24 and second 26 finger elements. This substantially increases the frequency with which the first 24 and second 30 spring elements move across portions of the first 28 and second 30 ink strips, thus increasing relative motion therebetween and causing accelerated wear of the first 28 and second 30 ink strips. A method for reducing the relative motion is to increase the spring force exerted by the first 24 and second 26 finger elements on the first 28 and second 30 ink strips. However, this results in an increased ink wear rate due to increased finger element contact pressure. Another method is to use more stringent mechanical clearances when fabricating the sensor. A disadvantage with this approach is that manufacturing costs are increased. In addition, further control of relative motion is desired in order to reduce the ink wear rate and ultimately increase the reliability of such sensors.

Referring to FIG. 2, portions of an alternate position sensor 46 such as that used in motor vehicle exhaust gas-recirculation (EGR) valves is shown. The sensor 46 includes a contactor arm 48 having a lower section 50 that is attached by a fastener 52 to an alternate plunger 54. The contactor arm 48 further includes an upper section 56 which extends outwardly from the lower section 50 and contacts an associated ink strip 29 on the board 32.

During use, the sensor 46 is subjected to vibrations which increase the relative motion between the second member 56 and the ink strip 29, resulting in accelerated wear of the ink strip 29. A major component of the relative motion is due to vibration of the contactor arm 48 which occurs at its natural frequency. As such, it is desirable to increase the natural frequency of the contactor arm 48 so as to separate it from the frequency of vibration to which the sensor 46 is exposed.

### SUMMARY OF THE INVENTION

A slider assembly for use in a position sensor having a board that includes ink strips. The slider assembly includes a base element having a plunger for attachment to an object whose position is being detected. Finger elements extend from the base element, wherein the finger elements contact the ink strips and are biased against the ink strips. A spring device having first and second spring elements is also included, wherein the first and second spring elements contact the board and are biased against the board to reduce relative motion between the finger elements and the ink strips.

The features of the invention believed to be novel are set forth with particularity in the appended claims. The invention itself, however, both as to organization and method of operation, may be best understood by reference to the following description taken in conjunction with the accompanying figures.

### BRIEF DESCRIPTION OF THE DRAWINGS

FIG. 1 is a perspective view of portions of a linear position sensor.

FIG. 2 is a side view of portions of a position sensor used in an exhaust gas recirculation valve for a motor vehicle.

FIG. 3 is a perspective view of spring device for controlling relative motion in accordance with the present invention.

FIG. 4 is a view of a stiffening member for increasing a natural frequency of a contactor arm used in a position sensor.

### DETAILED DESCRIPTION OF THE INVENTION

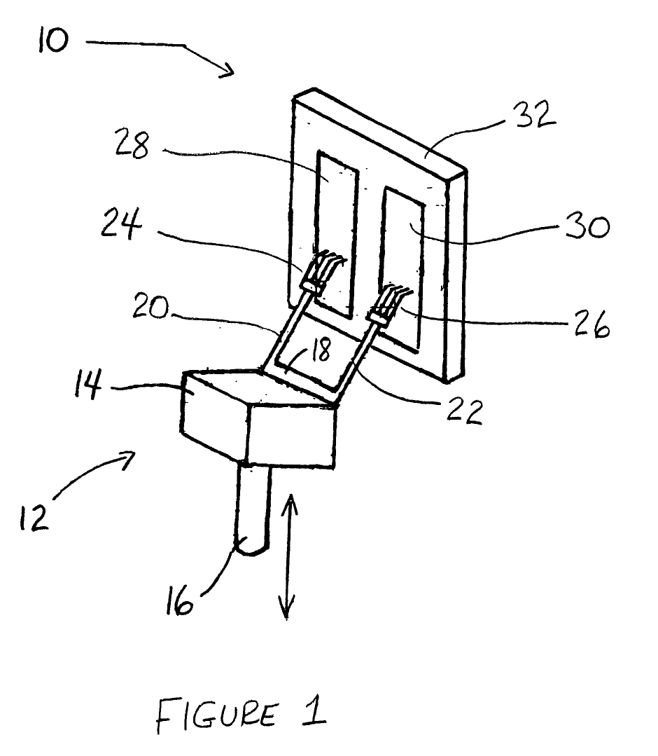

While this invention is susceptible of embodiment in many different forms, there is shown in the drawings and will herein be described in detail specific embodiments, with the understanding that the present disclosure is to be considered as an example of the principles of the invention and not intended to limit the invention to the specific embodiments shown and described. In the description below, like reference numerals are used to describe the same, similar or corresponding parts in the several views of FIGS. 1-4.

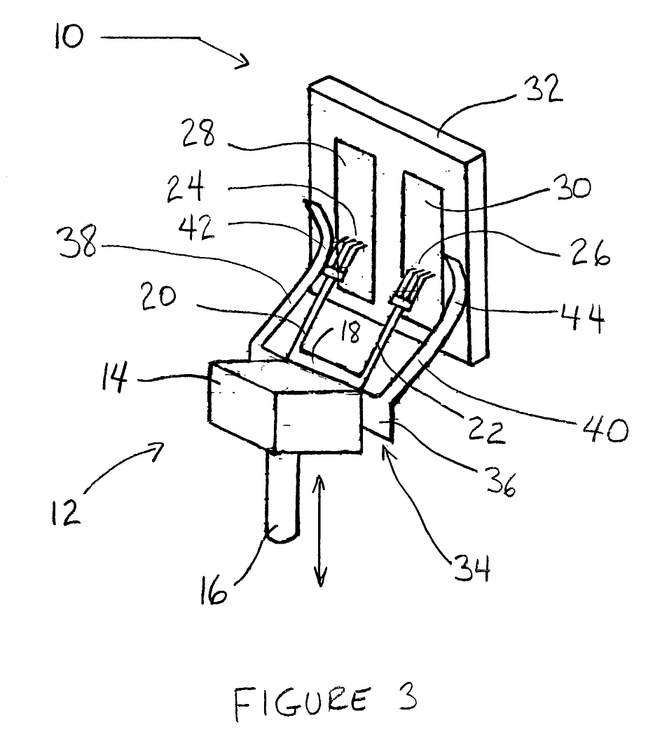

Referring to FIG. 3, a spring device 34 for controlling relative motion in a position sensor 10 is shown. The device 34 includes an attachment member 36 that is affixed to the base 14. The attachment member 36 is located between first 38 and second 40 spring elements that extend outwardly from the attachment member 36. The first 38 and second 40 spring elements include first 42 and second 44 contact surfaces, respectively, each having an arcuate shape adapted for contacting portions of the board 32 that do not have ink. In one embodiment, the first 42 and second 44 contact surfaces contact an area adjacent the first 28 and second 30 ink strips, respectively. Alternatively, the center member 18 and the attachment member 36 may be fabricated by using a stamping process to form a one piece assembly. In another configuration, the spring device 34, center member 18 and first 20 and second 22 arms may also be fabricated as one piece assembly.

The first 38 and second 40 spring elements are fabricated from a resilient material having spring properties. The first 38 and second 40 spring elements are positioned relative to the board 32 such that a spring force is exerted that biases the first 42 and second 44 contact surfaces against the board 32. In accordance with the present invention, this serves to increase the force that is exerted on the board 32, thus reducing relative motion between the first 24 and second 26 finger elements and the first 28 and second 30 ink strips, respectively. Further, the relative motion is reduced without increasing contact pressure between the first 24 and second 26 finger elements and the first 28 and second 30 ink strips, respectively, thus avoiding an increased ink wear rate.

Alternatively, the spring device 34 may be affixed to a sensor housing. However, it is preferable that the spring device 34 be located on the slider assembly 12 so that the contact points of first 24 and second 26 finger elements are co-linear with that of the first 42 and second 44 contact surfaces. Further, although the present invention is described in relation to linear position sensors, it is noted that the principles of the present invention may also be used in rotary position sensors.

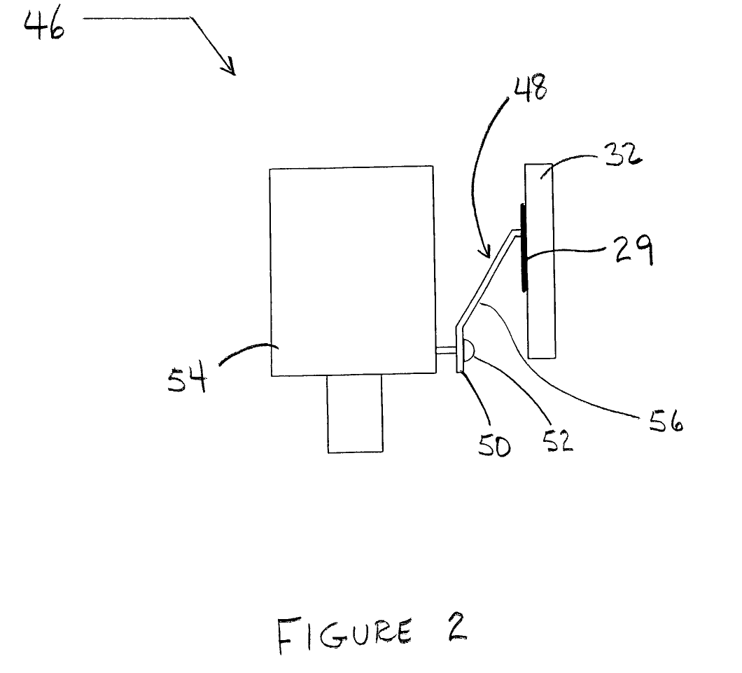

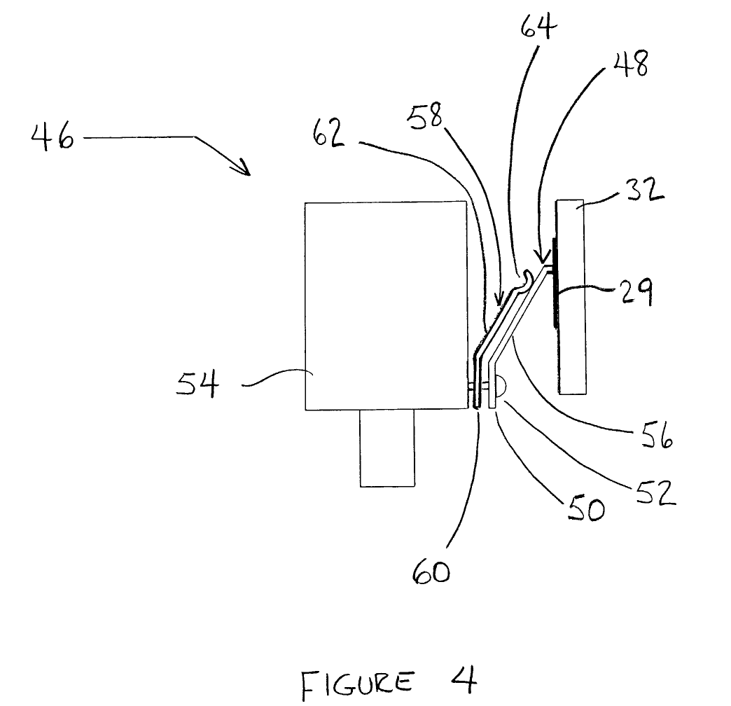

Referring to FIG. 4, a stiffening member 58 is shown for increasing the natural frequency of the contactor arm 48 described in relation to FIG. 2. The stiffening member 58 includes lower 60 and upper 62 portions which correspond to the shape of lower 50 and upper 56 sections, respectively, of the contactor arm 48. The upper portion 62 further includes a cup portion 64 having an arcuate shape. The stiffening member 58 is affixed to the alternate plunger 54 by the fastener 52 such that the cup portion 64 rigidly contacts the upper section 56 of the contactor arm 48. The stiffening member 58 serves to increase the stiffness and mass of the contactor arm 48, thus increasing its natural frequency. As a result, the natural frequency of the contactor arm 48 is separated from the frequency of vibration to which the sensor 46 is exposed, thus reducing relative motion between the contactor arm 48 and the ink strip 29.

While the invention has been described in conjunction with specific embodiments, it is evident that many alternatives, modifications, permutations and variations will become apparent to those skilled in the art in light of the foregoing description. In particular, it is noted that additional spring elements may be used or that the spring elements each include spring fingers. Accordingly, it is intended that the present invention embrace all such alternatives, modifications and variations as fall within the scope of the appended claims.

What is claimed is:

1. A slider assembly for use in a position sensor having a board that includes ink strips, comprising:
a base element having a plunger for attachment to an object whose position is being detected;
finger elements which extend from said base element, wherein said finger elements contact said ink strips and are biased against said ink strips; and
a spring device having first and second spring elements, wherein said first and second spring elements contact said board and are biased against said board to reduce relative motion between said finger elements and said ink strips.

2. The slider assembly according to claim 1, wherein said first and second spring elements each include arcuately shaped contact surfaces for contacting said board.

3. The slider assembly according to claim 1, wherein said spring device is affixed to said base element.

4. The slider assembly according to claim 1, wherein said spring device is affixed to a housing for said sensor.

5. The slider assembly according to claim 1, wherein said sensor is a linear position sensor.

6. The slider assembly according to claim 1, wherein said sensor is a rotary position sensor.

7. The slider assembly according to claim 1, wherein said finger elements and said spring device are formed as a one piece assembly.

8. A spring device for use in a position sensor having finger elements and a base element that includes a plunger for attachment to an object whose position is being detected, comprising:
a center member located between first and second spring elements, wherein said center member is affixed to said base element; and
contact surfaces formed on ends of said first and second spring elements, wherein said contact surfaces contact said board and are biased against said board to reduce relative motion of said finger elements.

9. The spring device according to claim 8, wherein contact surfaces are each arcuately shaped.

10. The slider assembly according to claim 8, wherein said spring device is affixed to a housing for said sensor.

11. The slider assembly according to claim 8, wherein said sensor is a linear position sensor.

12. The slider assembly according to claim 8, wherein said sensor is a rotary position sensor.

13. A method for reducing relative motion between finger elements and ink strips formed on a board used in a position sensor, comprising the steps of:
providing a spring device having contact surfaces for contacting portions of said board that do not have said ink; and
biasing said contact surfaces against said board to reduce relative motion between said finger elements and said ink strips.

14. The method according to claim 13, wherein said contact surface is arcuately shaped.

15. The method according to claim 13, wherein said sensor is a linear position sensor.

16. The method according to claim 13, wherein said sensor is rotary position sensor.

17. A method for reducing relative motion between a contactor arm affixed to a plunger and an ink strip formed on a board of a position sensor, wherein said relative motion is caused by vibration of said sensor, comprising the steps of:
providing a stiffening member having a cup portion; and
affixing said stiffening member to said plunger such that said cup portion contacts said contactor arm to increase a natural frequency of said contactor arm such that the natural frequency is separated from the frequency of vibration to which said sensor is exposed, thus reducing relative motion between said contactor arm and said ink strip.
